(19) United States
(12) Patent Application Publication
(10) Pub. No.: US 2023/0408588 A1
(43) Pub. Date: Dec. 21, 2023

(54) STORAGE SYSTEM CONFIGURED FOR USE WITH AN ENERGY MANAGEMENT SYSTEM

(71) Applicant: Enphase Energy, Inc., Petaluma, CA (US)

(72) Inventors: Wei JIANG, Round Rock, TX (US); Chris Morrow YOUNG, Round Rock, TX (US)

(21) Appl. No.: 18/196,213

(22) Filed: May 11, 2023

Related U.S. Application Data
(60) Provisional application No. 63/351,904, filed on Jun. 14, 2022.

(51) Int. Cl. G01R 31/382; G01R 31/389; H01M 10/48

(52) U.S. Cl. CPC G01R 31/382; H01M 10/48; G01R 31/389

(57) ABSTRACT

A storage system configured for use with an energy management system is provided and includes an AC rechargeable battery and a power converter operably coupled to the AC rechargeable battery and configured to calculate an estimate of state-of-charge of the AC rechargeable battery based on at least one of DC impedance of the AC rechargeable battery or AC impedance of the AC rechargeable battery that are measured in real time operation is used to calculate resistance and capacitance values for an equivalent circuit model that in conjunction with previously measured voltage and current are input to an extended kalman filter (EKF). Time consuming testing of the equivalent circuit model in advance is therefore eliminated.

### CROSS-REFERENCE TO RELATED APPLICATIONS

The present application claims the benefit of and priority to U.S. Provisional Application Ser. No. 63/351,904, filed on Jun. 14, 2022, the entire contents of which is incorporated herein by reference.

### BACKGROUND

### 1. Field of the Disclosure

Embodiments of the present disclosure generally relate to power systems and, more particularly, to methods and apparatus for calculating a state-of-charge (SoC) of a battery of a storage system.

### 2. Description of the Related Art

Conventional AC storage systems comprise one or more batteries (e.g., lithium-ion batteries) and provide a required energy storage (kWh) and a required AC power (kW). SoC is an important parameter of the lithium-ion battery in terms of indicating a proper battery state, providing an available energy, for calculating SoH (state-of-health), etc. Therefore, a high accuracy of the SoC is required (e.g., <2%).

Methods for determining a SoC can include a coulombic counting method, which is relatively easy to perform, but has relatively low accuracy, e.g., about 3% to about 5%, and requires frequent calibration. Extended kalman filter (EKF) is another method that can be used for determining a SoC, and while the EKF method provides a higher accuracy (e.g., <2%) and reasonable requirements on computing power, the EKF method requires a pre-established equivalent circuit model (ECM) as an input, which can take months and sometimes up to a year to calculate.

Therefore, the inventors have found improved methods and apparatus for calculating SoC of a battery.

### SUMMARY

In accordance with some aspects of the present disclosure, a storage system configured for use with an energy management system comprises an AC rechargeable battery and a power converter operably coupled to the AC rechargeable battery and configured to calculate an estimate of state-of-charge of the AC rechargeable battery based on at least one of DC impedance of the AC rechargeable battery or AC impedance of the AC rechargeable battery used to calculate resistance and capacitance values for an equivalent circuit module that in conjunction with previously measured voltage and current are input to an extended kalman filter (EKF).

In accordance with some aspects of the present disclosure, a method for managing a storage system configured for use with an energy management system comprises calculating an estimate of state-of-charge of an AC rechargeable battery based on at least one of DC impedance of the AC rechargeable battery or AC impedance of the AC rechargeable battery used to calculate resistance and capacitance values for an equivalent circuit module that in conjunction with previously measured voltage and current are input to an extended kalman filter (EKF).

In accordance with some aspects of the present disclosure, a non-transitory computer readable storage medium has stored thereon instructions that when executed by a processor perform a method for managing a storage system configured for use with an energy management system. The method comprises calculating an estimate of state-of-charge of an AC rechargeable battery based on at least one of DC impedance of the AC rechargeable battery or AC impedance of the AC rechargeable battery used to calculate resistance and capacitance values for an equivalent circuit module that in conjunction with previously measured voltage and current are input to an extended kalman filter (EKF).

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only a typical embodiment of this disclosure and are therefore not to be considered limiting of its scope, for the disclosure may admit to other equally effective embodiments.

FIG. 1 is a block diagram of a system for power conversion, in accordance with at least some embodiments of the present disclosure;

FIG. 2 is a block diagram of an AC battery system, in accordance with at least some embodiments of the present disclosure;

FIG. 3 is a diagram of an apparatus for determining a SoC of the AC battery system of FIG. 2, in accordance with at least some embodiments of the present disclosure; and

FIG. 4 is a flowchart of a method for managing a storage system configured for use with an energy management system, in accordance with at least one embodiment of the present disclosure.

### DETAILED DESCRIPTION

In accordance with the present disclosure, methods and apparatus for calculating a state-of-charge (SoC) of a battery of a storage system are disclosed herein. For example, methods described herein comprise using a PCU of the storage system to measure a real time battery impedance for SoC estimation with EKF. For example, in at least some embodiments, a method comprises measuring a battery DC impedance at a particular temperature, a current, and a SoC, calculating real time ECM as inputs to EKF and SoC estimation. Alternatively or additionally, in at least some embodiments, a method comprises measuring a battery AC (e.g., 120 Hz and/or other frequencies) impedance and using the measured AC battery impedance to calculate a real time ECM as input to EKF and SoC estimation. Both methods can also use an additional AC signal at a PCU switching frequency to measure the real ohmic value (e.g., the ECM, resistance (R), and capacitance (C), values) of a battery for calibrating data of an ECM calculation. The methods and apparatus described herein eliminate a need for using specific testing devices, eliminate a need of a time-consuming pretesting step (e.g., six (6) to twelve (12) months) for conventional EKF methods by applying an online measurement instead, and can be used to update a SoC model in the field over a life of a battery. Additionally, the methods and apparatus described herein eliminate a need for purchasing or sharing bandwidth of specific testing devices (e.g., >$30,000 for a four (4)-channel tester), reduce a time/labor cost (e.g., six (6) to twelve (12) months to build a database for conventional EKF), and can be sold as a kit (e.g., for additional revenue).

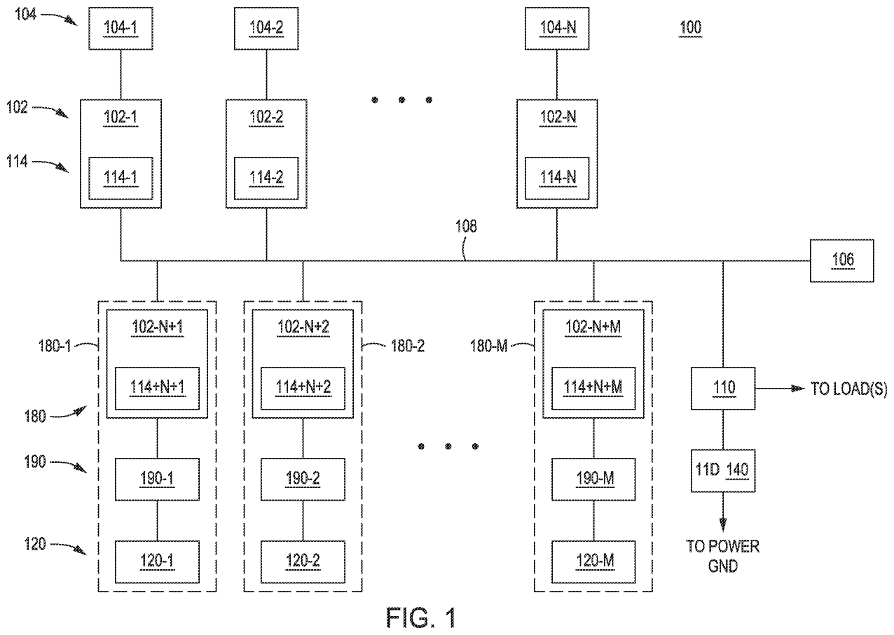

FIG. 1 is a block diagram of a system 100 (an energy management system) for power conversion using one or more embodiments of the present disclosure. This diagram only portrays one variation of the myriad of possible system configurations and devices that may utilize the present disclosure.

The system 100 is a microgrid that can operate in both an islanded state and in a grid-connected state (i.e., when connected to another power grid (such as one or more other microgrids and/or a commercial power grid). The system 100 comprises a plurality of power converters 102-1, 102-2, . . . 102-N, 102-N+1, and 102-N+M collectively referred to as power converters 102 (which also may be called power conditioners); a plurality of DC power sources 104-1, 104-2, . . . 104-N, collectively referred to as power sources 104; a plurality of energy storage devices/delivery devices 120-1, 120-2, . . . 120-M collectively referred to as energy storage/delivery devices 120; a system controller 106; a plurality of BMUs 190-1, 190-2, . . . 190-M (battery management units) collectively referred to as BMUs 190; a system controller 106; a bus 108; a load center 110; and an IID 140 (island interconnect device) (which may also be referred to as a microgrid interconnect device (MID)). In some embodiments, such as the embodiments described herein, the energy storage/delivery devices are rechargeable batteries (e.g., multi-C-rate collection of AC batteries) which may be referred to as batteries 120, although in other embodiments the energy storage/delivery devices may be any other suitable device for storing energy and providing the stored energy. Generally, each of the batteries 120 comprises a plurality of cells that are coupled in series, e.g., eight cells coupled in series to form a battery 120.

Each power converter 102-1, 102-2 . . . 102-N is coupled to a DC power source 104-1, 104-2 . . . 104-N, respectively, in a one-to-one correspondence, although in some other embodiments multiple DC power sources may be coupled to one or more of the power converters 102. The power converters 102-N+1, 102-N+2 . . . 102-N+M are respectively coupled to plurality of energy storage devices/delivery devices 120-1, 120-2 . . . 120-M via BMUs 190-1, 190-2 . . . 190-M to form AC batteries 180-1, 180-2 . . . 180-M, respectively. Each of the power converters 102-1, 102-2 . . . 102-N+M comprises a corresponding controller 114-1, 114-2 . . . 114-N+M (collectively referred to as the inverter controllers 114) for controlling operation of the power converters 102-1, 102-2 . . . 102-N+M.

In some embodiments, such as the embodiment described below, the DC power sources 104 are DC power sources and the power converters 102 are bidirectional inverters such that the power converters 102-1 . . . 102-N convert DC power from the DC power sources 104 to grid-compliant AC power that is coupled to the bus 108, and the power converters 102-N+1 . . . 102-N+M convert (during energy storage device discharge) DC power from the batteries 120 to grid-compliant AC power that is coupled to the bus 108 and also convert (during energy storage device charging) AC power from the bus 108 to DC output that is stored in the batteries 120 for subsequent use. The DC power sources 104 may be any suitable DC source, such as an output from a previous power conversion stage, a battery, a renewable energy source (e.g., a solar panel or photovoltaic (PV) module, a wind turbine, a hydroelectric system, or similar renewable energy source), or the like, for providing DC power. In other embodiments the power converters 102 may be other types of converters (such as DC-DC converters), and the bus 108 is a DC power bus.

The power converters 102 are coupled to the system controller 106 via the bus 108 (which also may be referred to as an AC line or a grid). The system controller 106 generally comprises a CPU coupled to each of support circuits and a memory that comprises a system control module for controlling some operational aspects of the system 100 and/or monitoring the system 100 (e.g., issuing certain command and control instructions to one or more of the power converters 102, collecting data related to the performance of the power converters 102, and the like). The system controller 106 is capable of communicating with the power converters 102 by wireless and/or wired communication (e.g., power line communication) for providing certain operative control and/or monitoring of the power converters 102.

In some embodiments, the system controller 106 may be a gateway that receives data (e.g., performance data) from the power converters 102 and communicates (e.g., via the Internet) the data and/or other information to a remote device or system, such as a master controller (not shown). Additionally or alternatively, the gateway may receive information from a remote device or system (not shown) and may communicate the information to the power converters 102 and/or use the information to generate control commands that are issued to the power converters 102.

The power converters 102 are coupled to the load center 110 via the bus 108, and the load center 110 is coupled to the power grid via the IID 140. When coupled to the power grid (e.g., a commercial grid or a larger microgrid) via the IID 140, the system 100 may be referred to as grid-connected; when disconnected from the power grid via the IID 140, the system 100 may be referred to as islanded. The IID 140 determines when to disconnect from/connect to the power grid (e.g., the IID 140 may detect a grid fluctuation, disturbance, outage or the like) and performs the disconnection/connection. Once disconnected from the power grid, the system 100 can continue to generate power as an intentional island, without imposing safety risks on any line workers that may be working on the grid, using the droop control techniques described herein. The IID 140 comprises a disconnect component (e.g., a disconnect relay) for physically disconnecting/connecting the system 100 from/to the power grid. In some embodiments, the IID 140 may additionally comprise an autoformer for coupling the system 100 to a split-phase load that may have a misbalance in it with some neutral current. In certain embodiments, the system controller 106 comprises the IID 140 or a portion of the IID 140.

The power converters 102 convert the DC power from the DC power sources 104 and discharging batteries 120 to grid-compliant AC power and couple the generated output power to the load center 110 via the bus 108. The power is then distributed to one or more loads (for example to one or more appliances) and/or to the power grid (when connected to the power grid). Additionally or alternatively, the generated energy may be stored for later use, for example using batteries, heated water, hydro pumping, H₂O-to-hydrogen conversion, or the like. Generally, the system 100 is coupled to the commercial power grid, although in some embodiments the system 100 is completely separate from the commercial grid and operates as an independent microgrid.

In some embodiments, the AC power generated by the power converters 102 is single-phase AC power. In other embodiments, the power converters 102 generate three-phase AC power.

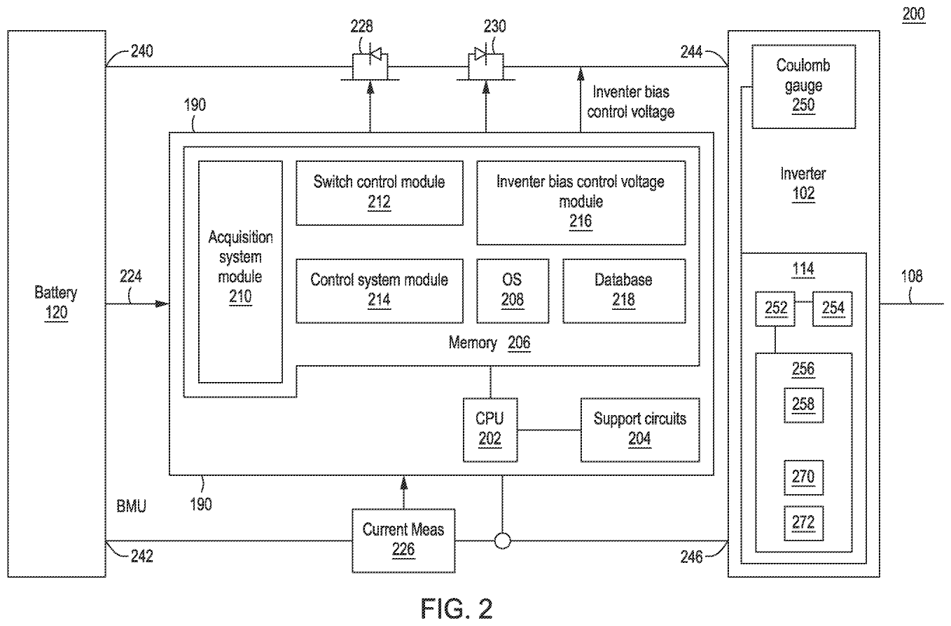

A storage system configured for use with an energy management system, such as the Enphase® Energy System, is described herein. For example, FIG. 2 is a block diagram of an AC battery system 200 (e.g., a storage system) in accordance with one or more embodiments of the present disclosure.

The AC battery system 200 comprises a BMU 190 coupled to a battery 120 and a power converter 102. A pair of metal-oxide-semiconductor field-effect transistors (MOSFETs) switches—switches 228 and 230—are coupled in series between a first terminal 240 of the battery 120 and a first terminal of the inverter 144 such the body diode cathode terminal of the switch 228 is coupled to the first terminal 240 of the battery 120 and the body diode cathode terminal of the switch 230 is coupled to the first terminal 244 of the power converter 102. The gate terminals of the switches 228 and 230 are coupled to the BMU 190.

A second terminal 242 of the battery 120 is coupled to a second terminal 246 of the power converter 102 via a current measurement module 226 which measures the current flowing between the battery 120 and the power converter 102.

The BMU 190 is coupled to the current measurement module 226 for receiving information on the measured current, and also receives an input 224 from the battery 120 indicating the battery cell voltage and temperature. The BMU 190 is coupled to the gate terminals of each of the switches 228 and 230 for driving the switch 228 to control battery discharge and driving the switch 230 to control battery charge as described herein. The BMU 190 is also coupled across the first terminal 244 and the second terminal 246 for providing an inverter bias control voltage (which may also be referred to as a bias control voltage) to the inverter 102 as described further below.

The configuration of the body diodes of the switches 228 and 230 allows current to be blocked in one direction but not the other depending on state of each of the switches 228 and 230. When the switch 228 is active (i.e., on) while the switch 230 is inactive (i.e., off), battery discharge is enabled to allow current to flow from the battery 120 to the power converter 102 through the body diode of the switch 230. When the switch 228 is inactive while the switch 230 is active, battery charge is enabled to allow current flow from the power converter 102 to the battery 120 through the body diode of the switch 228. When both switches 228 and 230 are active, the system is in a normal mode where the battery 120 can be charged or discharged.

The BMU 190 comprises support circuits 204 and a memory 206 (e.g., non-transitory computer readable storage medium), each coupled to a CPU 202 (central processing unit). The CPU 202 may comprise one or more processors, microprocessors, microcontrollers and combinations thereof configured to execute non-transient software instructions to perform various tasks in accordance with embodiments of the present disclosure. The CPU 202 may additionally or alternatively include one or more application specific integrated circuits (ASICs). In some embodiments, the CPU 202 may be a microcontroller comprising internal memory for storing controller firmware that, when executed, provides the controller functionality described herein. The BMU 190 may be implemented using a general purpose computer that, when executing particular software, becomes a specific purpose computer for performing various embodiments of the present disclosure.

The support circuits 204 are well known circuits used to promote functionality of the CPU 202. Such circuits include, but are not limited to, a cache, power supplies, clock circuits, buses, input/output (I/O) circuits, and the like. The BMU 190 may be implemented using a general purpose computer that, when executing particular software, becomes a specific purpose computer for performing various embodiments of the present disclosure. In one or more embodiments, the CPU 202 may be a microcontroller comprising internal memory for storing controller firmware that, when executed, provides the controller functionality described herein.

The memory 206 may comprise random access memory, read only memory, removable disk memory, flash memory, and various combinations of these types of memory. The memory 206 is sometimes referred to as main memory and may, in part, be used as cache memory or buffer memory. The memory 206 generally stores an OS 208 (operating system), if necessary, of the inverter controller 114 that can be supported by the CPU capabilities. In some embodiments, the OS 208 may be one of a number of commercially available operating systems such as, but not limited to, LINUX, Real-Time Operating System (RTOS), and the like.

The memory 206 stores non-transient processor-executable instructions and/or data that may be executed by and/or used by the CPU 202 to perform, for example, one or more methods for discharge protection, as described in greater detail below. These processor-executable instructions may comprise firmware, software, and the like, or some combination thereof. The memory 206 stores various forms of application software, such as an acquisition system module 210, a switch control module 212, a control system module 214, and an inverter bias control module 216. The memory 206 additionally stores a database 218 for storing data related to the operation of the BMU 190 and/or the present disclosure, such as one or more thresholds, equations, formulas, curves, and/or algorithms for the control techniques described herein. In various embodiments, one or more of the acquisition system module 210, the switch control module 212, the control system module 214, the inverter bias control module 216, and the database 218, or portions thereof, are implemented in software, firmware, hardware, or a combination thereof.

The acquisition system module 210 obtains the cell voltage and temperature information from the battery 120 via the input 224, obtains the current measurements provided by the current measurement module 226, and provides the cell voltage, cell temperature, and measured current information to the control system module 214 for use as described herein.

The switch control module 212 drives the switches 228 and 230 as determined by the control system module 214. The control system module 214 provides various battery management functions, including protection functions (e.g., overcurrent (OC) protection, overtemperature (OT) protection, and hardware fault protection), metrology functions (e.g., averaging measured battery cell voltage and battery current over, for example, 100 ms to reject 50 and 60 Hz ripple), state of charge (SOC) analysis (e.g., coulomb gauge 250 for determining current flow and utilizing the current flow in estimating the battery SOC; synchronizing estimated SOC values to battery voltages (such as setting SOC to an upper bound, such as 100%, at maximum battery voltage; setting SOC to a lower bound, such as 0%, at a minimum battery voltage); turning off SOC if the power converter 102 never drives the battery 120 to these limits; and the like), balancing (e.g., autonomously balancing the charge across all cells of a battery to be equal, which may be done at the end of charge, at the end of discharge, or in some embodiments both at the end of charge and the end of discharge). By establishing upper and lower estimated SOC bounds based on battery end of charge and end of discharge, respectively, and tracking the current flow and cell voltage (i.e., battery voltage) between these events, the BMU 190 determines the estimated SOC.

The inverter controller 114 comprises support circuits 254 and a memory 256, each coupled to a CPU 252 (central processing unit). The CPU 252 may comprise one or more processors, microprocessors, microcontrollers and combinations thereof configured to execute non-transient software instructions to perform various tasks in accordance with embodiments of the present disclosure. The CPU 252 may additionally or alternatively include one or more application specific integrated circuits (ASICs). In some embodiments, the CPU 252 may be a microcontroller comprising internal memory for storing controller firmware that, when executed, provides the controller functionality herein. The inverter controller 114 may be implemented using a general purpose computer that, when executing particular software, becomes a specific purpose computer for performing various embodiments of the present disclosure.

The support circuits 254 are well known circuits used to promote functionality of the CPU 252. Such circuits include, but are not limited to, a cache, power supplies, clock circuits, buses, input/output (I/O) circuits, and the like. The inverter controller 114 may be implemented using a general purpose computer that, when executing particular software, becomes a specific purpose computer for performing various embodiments of the present disclosure. In one or more embodiments, the CPU 252 may be a microcontroller comprising internal memory for storing controller firmware that, when executed, provides the controller functionality described herein.

The memory 256 may comprise random access memory, read only memory, removable disk memory, flash memory, and various combinations of these types of memory. The memory 256 is sometimes referred to as main memory and may, in part, be used as cache memory or buffer memory. The memory 256 generally stores the OS 258, if necessary, of the inverter controller 114 that can be supported by the CPU capabilities. In some embodiments, the OS 258 may be one of a number of commercially available operating systems such as, but not limited to, LINUX, Real-Time Operating System (RTOS), and the like.

The memory 256 stores non-transient processor-executable instructions and/or data that may be executed by and/or used by the CPU 252. These processor-executable instructions may comprise firmware, software, and the like, or some combination thereof. The memory 256 stores various forms of application software, such as a power conversion control module 270 for controlling the bidirectional power conversion, and a battery management control module 272.

The BMU 190 communicates with the system controller 106 to perform balancing of the batteries 120 (e.g., multi-C-rate collection of AC batteries) based on a time remaining before each of the batteries are depleted of charge, to perform droop control (semi-passive) which allows the batteries to run out of charge at substantially the same time, and perform control of the batteries to charge batteries having less time remaining before depletion using batteries having more time remaining before depletion, as described in greater detail below.

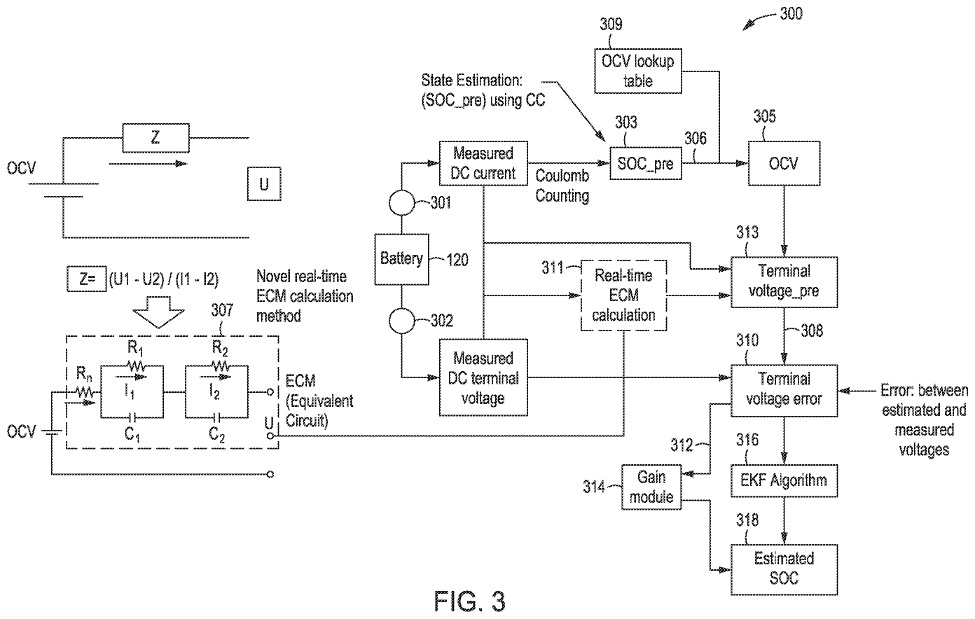

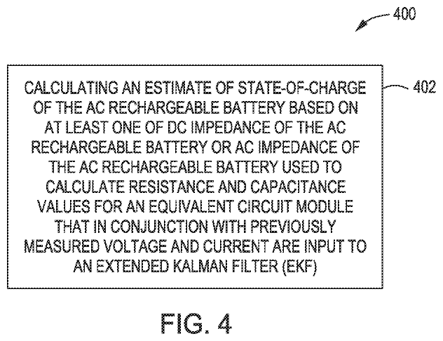

FIG. 3 is a diagram of an apparatus for determining a SoC of the AC battery system of FIG. 2, and FIG. 4 is a flowchart of a method 400 for managing a storage system configured for use with an energy management system, in accordance with at least one embodiment of the present disclosure.

For example, at 402, the method 400 comprises calculating an estimate of state-of-charge of an AC rechargeable battery based on at least one of DC impedance of the AC rechargeable battery or AC impedance of the AC rechargeable battery (that are calculated in real-time when the AC rechargeable battery is operating) used to calculate resistance and capacitance values for an equivalent circuit module (ECM) that in conjunction with previously measured voltage and current are input to an extended kalman filter (EKF).

For example, as noted above, the power converter 102 can be operably coupled to the battery 120 (e.g., an AC rechargeable battery) and can be configured to calculate an estimate of state-of-charge of the AC rechargeable battery. For example, in at least some embodiments, when an estimate of state-of-charge of the AC rechargeable battery is based on DC impedance, the method 400 can comprise the inverter controller 114 measuring voltage and current at a time 1 and a time 2 (see FIGS. 3, at 301 and 302, respectively. In at least some embodiments, a duration from the time 1 to the time 2 can be about 1 second to about 1 minute. In at least some embodiments, the time 1 to the time 2 can be about 10 seconds. In at least some embodiments, a duration from the time 1 to the time 2 or can vary based on a chemistry of the AC rechargeable battery). In at least some embodiments, the voltage can be taken across the battery 120 and one or more suitable current sensors 301 can be used to measure the current flowing from the battery 120. The measured current is input to a module 303 (e.g., transistor Q1), which can be used to select an appropriate battery SoC model.

Next, the power converter can be configured to calculate a preliminary state-of-charge_pre1 and a preliminary state-of-charge_pre2 based on a coulomb count taken at the time 1 and the time 2. For example, the inverter controller 114 can use the module 303 and the coulomb gauge 250 to perform coulomb counting to calculate the preliminary (rough) state-of-charge_pre1 and a preliminary state-of-charge_pre2. For example, coulomb counting can be taken at beginning of the 10 second duration (e.g., time 1) and at an ending of the 10 second duration (e.g., time 2) to calculate a SoC_pre1 and a SoC_pre2, respectively (see FIG. 3 at 306). The SoC_pre1 and the SoC_pre2 values along with the measured current are input to a module 305 (e.g., transistor Q2), which can be used to select an appropriate battery voltage model, as described in greater detail below.

At module 311, the power converter can use curve fitting to determine the resistance and capacitance values in the ECM 307 using the calculated DC impedance Z calculated with the measured V and I or directly with the measured V and I. For example, the power converter can calculate DC impedance Z between the SoC_pre1 and a SoC_pre2 (e.g., using the corresponding measured voltages and current at time 1 and time 2, (V₁-V₂)/(I₁-I₂)). In at least some embodiments, the DC impedance of the AC rechargeable battery can be determined for a predetermined temperature of the AC rechargeable battery and/or a C-rate of the AC rechargeable battery. The power converter can decompose the DC impedance into corresponding resistance and capacitance values (e.g., using curve fitting at the predetermined temperature of the AC rechargeable battery and/or a C-rate of the AC rechargeable battery between the SoC_pre1 and a SoC_pre2). Open circuit voltage_pre2 can be calculated with the SoC_pre2 and a look-up table comprising open circuit voltages and corresponding preliminary state-of-charges (vendor provided and/or internal measurements). The open-circuit-voltage_pre2, the measured I (e.g., last data point of the 1 second measurement), and the resistance and capacitance values in the ECM 307 can be used to determine the estimated terminal voltages (e.g., model voltage). The estimated terminal voltages can be input at 308 to a module 310, which can be a comparator/subtractor and a voltage error between the estimated terminal voltages and the measured voltages can be determined. The voltage error can be input at 312 to a gain module 314 (e.g., transistor Q3). The output of the gain module 314 is input, along with the preliminary state-of-charge_pre2, to the EKF 316 where the estimated SoC 318 can be determined.

In at least some embodiments, such as when the at least one of AC impedance of the AC rechargeable battery is used to calculate the estimate of state-of-charge of the AC rechargeable battery, the previously measured voltage and current can be determined at a time 1. For example, 120 Hz voltage and current sine waves can be extracted from the power converter DC side voltage and current data at the time 1 (e.g., about 1 second) and voltage and current raw data can be obtained using, for example, with FFT (Fast Fourier transform) analysis (e.g., calculate voltage and current of AC signals with certain frequencies embedded in the power converter DC voltage and current). The value of the AC impedance can be calculated by dividing the voltage (v) (120 Hz) with current (i) (120 Hz). Additionally, the calculated AC impedances can be used to curve fit the resistance, capacitance values in the ECM, as described above. The state-of-charge_pre at the end of the time 1 raw data can be estimated with coulomb counting, and corresponding open circuit voltage_prel can be estimated as described above. Thereafter, the state-of-charge_pre and the LUT can be used to estimate the open-circuit-voltage_pre, which can be used to get the estimated terminal voltage together with the I (e.g., last data point of the 1 second measurement) and the ECM. The measured voltage (e.g., last data point of the 1 second measurement) and the estimated terminal voltage can be fed into the EKF as inputs for the error, then the gain, and finally the SoC estimation, as described above.

Alternatively, instead of measuring the signal of 120 Hz only, signals at multiple frequencies can be measured, and the resistance and capacitance values of the ECM can be isolated from the signals from different frequencies and calculated, using known methods.

While the foregoing is directed to embodiments of the present disclosure, other and further embodiments of the disclosure may be devised without departing from the basic scope thereof, and the scope thereof is determined by the claims that follow.

1. A storage system configured for use with an energy management system, comprising:
an AC rechargeable battery; and
a power converter operably coupled to the AC rechargeable battery and configured to calculate an estimate of state-of-charge of the AC rechargeable battery based on at least one of a DC impedance of the AC rechargeable battery or an AC impedance of the AC rechargeable battery used to calculate resistance and capacitance values for an equivalent circuit module that in conjunction with a previously measured voltage and current are input to an extended kalman filter (EKF).

2. The storage system of claim 1, wherein, when the DC impedance of the AC rechargeable battery is used to calculate the estimate of state-of-charge of the AC rechargeable battery, the previously measured voltage and current are determined at a time 1 and a time 2.

3. The storage system of claim 2, wherein a duration from the time 1 to the time 2 is about 1 second to about 1 minute.

4. The storage system of claim 2, wherein the power converter is further configured to calculate a preliminary state-of-charge_pre1 and a preliminary state-of-charge_pre2 based on a coulomb count taken at the time 1 and the time 2.

5. The storage system of claim 4, wherein the power converter is further configured to determine an estimate open circuit voltage_pre1 and an open circuit voltage_pre2 based on the preliminary state-of-charge_pre1 and the preliminary state-of-charge_pre2, respectively, using a look-up table comprising open circuit voltages and corresponding preliminary state-of-charges.

6. The storage system of claim 1, wherein, the DC impedance and the AC impedance of the AC rechargeable battery are determined for at least one of a predetermined temperature of the AC rechargeable battery or a C-rate of the AC rechargeable battery.

7. The storage system of claim 1, wherein, when the AC impedance of the AC rechargeable battery is used to calculate the estimate of state-of-charge of the AC rechargeable battery, the previously measured voltage and current are determined at a time 1.

8. The storage system of claim 7, wherein a duration of the time 1 is about 1 second to about 1 minute.

9. The storage system of claim 7, wherein the power converter is further configured to perform a Fast Fourier transform analysis to calculate voltage and current of AC signals with certain frequencies embedded in the power converter DC voltage and current.

10. The storage system of claim 7, wherein the power converter is further configured to perform curve fitting to calculate resistance and capacitance values for the equivalent circuit module in real time while the power converter is operating.

11. A method for managing a storage system configured for use with an energy management system, comprising calculating an estimate of state-of-charge of an AC rechargeable battery based on at least one of a DC impedance of the AC rechargeable battery or an AC impedance of the AC rechargeable battery used to calculate resistance and capacitance values for an equivalent circuit module that in conjunction with previously measured voltage and current are input to an extended kalman filter (EKF).

12. The method of claim 11, wherein, when the DC impedance of the AC rechargeable battery is used to calculate the estimate of state-of-charge of the AC rechargeable battery, the previously measured voltage and current are determined at a time 1 and a time 2.

13. The method of claim 12, wherein a duration from the time 1 to the time 2 is about 1 second to about 1 minute.

14. The method of claim 12, further comprising calculating a preliminary state-of-charge_pre1 and a preliminary state-of-charge_pre2 based on a coulomb count taken at the time 1 and the time 2.

15. The method of claim 14, further comprising determining an open circuit voltage_pre1 and an open circuit voltage_pre2 based on the preliminary state-of-charge_pre1 and the preliminary state-of-charge_pre2, respectively, using a look-up table comprising open circuit voltages and corresponding preliminary state-of-charges.

16. The method of claim 11, wherein, the DC impedance and the AC impedance of the AC rechargeable battery are determined for at least one of a predetermined temperature of the AC rechargeable battery or a C-rate of the AC rechargeable battery.

17. The method of claim 11, wherein, when the AC impedance of the AC rechargeable battery is used to calculate the estimate of state-of-charge of the AC rechargeable battery, the previously measured voltage and current are determined at a time 1.

18. The method of claim 17, wherein a duration of the time 1 is about 1 second to about 1 minute.

19. The method of claim 17, further comprising performing a Fast Fourier transform analysis to calculate voltage and current of AC signals with certain frequencies embedded in the power converter DC voltage and current.

20. A non-transitory computer readable storage medium having stored thereon instructions that when executed by a process perform a method for managing a storage system configured for use with an energy management system, comprising calculating an estimate of state-of-charge of an AC rechargeable battery based on at least one of DC impedance of the AC rechargeable battery or AC impedance of the AC rechargeable battery used to calculate resistance and capacitance values for an equivalent circuit module that in conjunction with previously measured voltage and current are input to an extended kalman filter (EKF).
